(19) United States
(12) Patent Application Publication
(10) Pub. No.: US 2019/0355856 A1
(43) Pub. Date: Nov. 21, 2019

(54) TUNABLE EARTH ABUNDANT, NON-TOXIC PHOTOVOLTAIC DEVICES FOR LOW LIGHT AND VARIABLE LIGHT LEVEL POWER APPLICATIONS

(71) Applicant: International Business Machines Corporation, Armonk, NY (US)

(72) Inventors: Priscilla D. Antunez, Lisle, IL (US); Douglas M. Bishop, New York City, NY (US); Richard A. Haight, Mahopac, NY (US); Yu Luo, Hopewell Junction, NY (US)

(21) Appl. No.: 15/979,802

(22) Filed: May 15, 2018

(51) Int. Cl. H01L 31/032; H01L 31/05; H02S 40/38; H01L 31/0224; H01L 31/18

(52) U.S. Cl. CPC H01L 31/0326; H01L 31/0504; H01L 31/1884; H01L 31/022466; H02S 40/38

(57) ABSTRACT

A method of fabricating a photovoltaic device includes performing fabrication operations to form the photovoltaic device. The fabrication operations include replacing a portion of selenium with sulfur in a copper zinc tin sulfur selenium alloy (CZTSSe) material arranged on a substrate to form a sulfur enriched CZTSSe material to alter a band gap of the CZTSSe material. The fabrication operations include removing surface secondary phases or degraded portions of the sulfur enriched CZTSSe material to form a single phase sulfur enriched CZTSSe material. The fabrication operations further include replacing the substrate in contact with the single phase sulfur enriched CZTSSe material with a different contact material to form an exfoliated sulfur enriched CZTSSe device.

### STATEMENT REGARDING PRIOR DISCLOSURES BY THE INVENTOR OR A JOINT INVENTOR

The following disclosures are submitted under 35 U.S.C. 102(b)(1)(A):

DISCLOSURE(S): Efficient Kesterite Solar Cells with High Open-Circuit Voltage for Applications in Powering Distributed Devices, P. D. Antunez, D. M. Bishop, Y. Luo, and R. Haight, Nature Energy, Vol. 2, November 2017, pp. 884-890; and
Supplementary Information; Efficient Kesterite Solar Cells with High Open-Circuit Voltage for Applications in Powering Distributed Devices, P. D. Antunez, D. M. Bishop, Y. Luo, and R. Haight, Nature Energy, Vol. 2, November 2017, pp. 884-890.

### BACKGROUND

The present invention generally relates to fabrication methods and resulting structures for photovoltaic devices. More specifically, the present invention relates to tunable earth abundant, non-toxic photovoltaic devices used as solar cells for low light and variable level power applications.

Photovoltaic devices include semiconducting materials that exhibit the photovoltaic effect. The photovoltaic effect is a process by which electricity is generated based directly on exposure to light. Photovoltaic systems (e.g., solar cells) supply usable electrical energy and are increasingly used as alternatives to traditional fossil fuel-based energy sources. Photovoltaic devices can be used in low light situations, such as inside a structure, to power switches or sensors. Energy produced by photovoltaic/solar technology can generate a savings both in terms of costs and in its impact on the environment.

### SUMMARY

Embodiments of the present invention are directed to a method of fabricating a photovoltaic device. A non-limiting example of the method includes performing fabrication operations to form the photovoltaic device. The fabrication operations include replacing a portion of selenium with sulfur in a copper zinc tin sulfur selenium alloy (CZTSSe) material arranged on a substrate to form a sulfur enriched CZTSSe material to alter a band gap of the CZTSSe material. The fabrication operations include removing surface secondary phases or degraded portions of the sulfur enriched CZTSSe material to form a single phase sulfur enriched CZTSSe material. The fabrication operations further include replacing the substrate in contact with the single phase sulfur enriched CZTSSe material with a different contact material to form an exfoliated sulfur enriched CZTSSe device.

Another non-limiting example of the method includes performing fabrication operations to form the photovoltaic device. The fabrication operations include replacing a portion of selenium with sulfur in a copper zinc tin sulfur selenium alloy (CZTSSe) material arranged on a substrate to form a sulfur enriched CZTSSe material to alter a band gap of the CZTSSe material. The fabrication operations include annealing the sulfur enriched CZTSSe material in air, and removing surface secondary phases or degraded portions of the sulfur enriched CZTSSe material to form a single phase sulfur enriched CZTSSe material. The fabrication operations further include exposing a surface of the single phase sulfur enriched CZTSSe material in contact with the substrate and depositing a contact material on the surface to form an exfoliated sulfur enriched CZTSSe device.

Embodiments of the present invention are directed to a photovoltaic device. A non-limiting example of the photovoltaic device includes a battery. The photovoltaic device further includes a plurality of light absorbing stacks coupled to one another in series and arranged on the battery. Each light absorbing stack of the plurality includes a sulfur enriched copper zinc tin sulfur selenium alloy (CZTSSe) material arranged on a first contact, a buffer layer arranged on the sulfur enriched CZTSSe material, and a transparent electrode arranged on the buffer layer.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a diagram of a known circuit configured and arranged to model the behavior of a photovoltaic device;

FIG. 2 depicts a cross-sectional side view of a solar cell stack according to embodiments of the invention;

FIG. 3 depicts a method of replacing a substrate of a solar cell stack with a back contact according to embodiments of the invention;

FIG. 4 depicts a cross-sectional side view of solar cell stacks connected in series to form a photovoltaic device according to embodiments of the invention;

FIG. 5 depicts a flow diagram illustrating a method for forming a photovoltaic device according to embodiments of the invention;

FIG. 6 depicts a graph illustrating an increase in open current voltage after sulfur enrichment of a photovoltaic device according to embodiments of the invention; and

FIG. 7 depicts a diagram of a photovoltaic device as viewed from the back surface according to embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, autonomous, low power computers and sensors will be increasingly used in a variety of applications. For example, such computers and sensors can be used to monitor the state of a product or otherwise independent entity (e.g., a tree in an orchard, livestock, or room or building where wired power is not readily available). These systems must harvest energy from the local environment.

In order to power a small, low power autonomous computer or sensor, there are several energy constraints. A typical microcomputer, microprocessor, or microcontroller consumes power according to Equation I:

P=CV²f, Equation I

wherein C is the capacitance, V is the minimum threshold voltage required by the internal devices (e.g., transistors, memory, etc.), and f is the frequency of the computer. For example, a low power microcontroller can consume 30 W at a clock speed of 1 MHz, but only 3 W at 100 kHz. Nonetheless, the minimum voltage at which the transistor will operate is typically between 1 and 2.5 V.

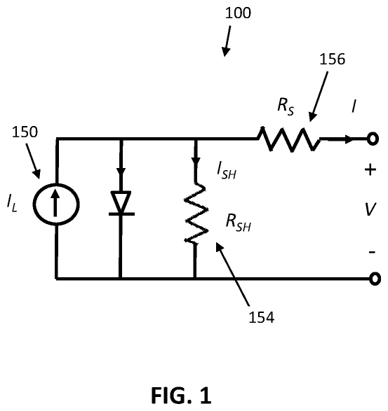

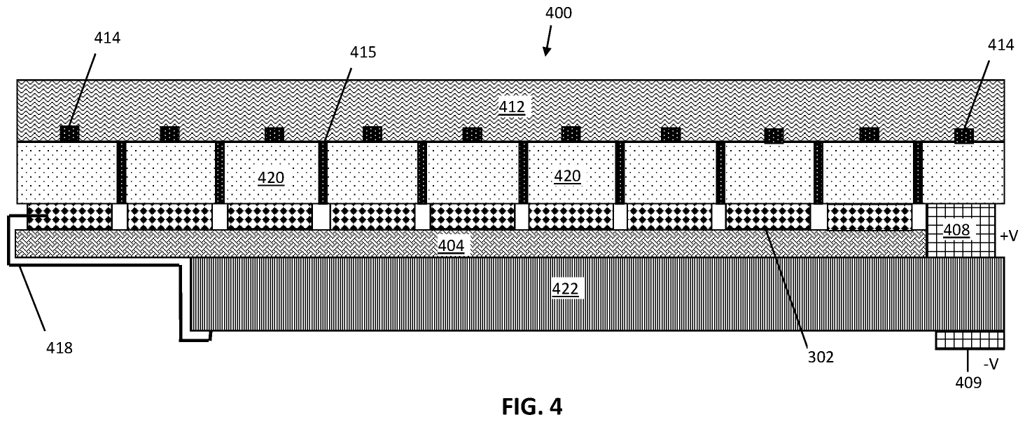

The ability of a photovoltaic (PV) device to supply at least the needed threshold voltage and sufficient current is challenging, however, particularly at low light levels. The voltage that a PV device supplies is dependent upon a number of properties. FIG. 1 depicts a schematic diagram of a known circuit 100 configured and arranged to model the behavior of a PV solar cell (e.g., solar cell 420 shown in FIG. 4). Circuit 100 includes a current source 150, a diode 152, a shunt resistor 154 (R_{SH}), and a series resistor 156 (Rₛ), configured and arranged as shown. Considering the PV solar cell modelled by the circuit 100 shown in FIG. 1, I_{L}, I_{D}, and I_{SH} are the light generated current, diode current, and current flowing across any shunts in the device, respectively. The current, I, that flows through the device the solar cell is driving is equal to Equation II:

I=I_{L}−I_{D}−I_{SH} Equation II

Equation II shows that the current generated by the light absorbed in a solar cell is reduced by the diode current (I_{D}), which is small, as well as any current that flows across the shunt (I_{SH}). For a high R_{SH}, little current will flow in this area, and the operating voltage of the device will remain high. The open circuit voltage (V_{OC}) is related to the current according to Equation III:

V_{OC}˜nKT/q[ln(I_{SC}/I₀+1)], Equation III

wherein I₀ is the reverse saturation current associated with electron-hole recombination, n is the diode ideality factor (how close the actual diode performs relative to the diode equation), K is the Boltzmann constant, T is the temperature in Kelvin, q is the elementary charge of an electron, and I_{sc} is the short circuit current. Thus, the open circuit voltage (V_{OC}) is only logarithmically related to the current.

Another challenge of powering an autonomous device is the ability to harness the particular spectrum of light produced from the environmental light source. Light from the sun is given by a blackbody spectrum, such that infrared light, below the band gap, is not absorbed; and photons with energy above the bandgap loose the excess energy to thermalization, which limits the efficiency of short wavelength light. The peak power conversion efficiency occurs for light slightly below the bandgap of the solar cell. Indoor light, such as fluorescent lights produce most of its light at wavelengths below 700 nm, which are absorbed, but far above the bandgap of typical solar cell materials, thus are not captured at peak efficiency. Further, in many fluorescent light settings, light intensity is low and can significantly vary (e.g., from 1 sun (sunlight level irradiance) to about 10⁻³ to 10⁻⁴ suns or more). Low light intensities can create specific challenges for solar cell operation, which further reduce solar cell efficiency.

The above described challenges must be resolved and optimized in a PV device. For a solar cell to operate with sufficient efficiency and sufficient voltage, the band gap of the absorber must be large enough to produce the proper voltages, and the shunt resistance must be high enough to minimize current losses at low light levels.

A thin film PV provides advantages in terms of cost of materials and deposition. For example, thin films can be deposited onto flexible substrates and fabricated using a wide range of methods. Yet, the voltage and shunt resistance of the thin film PV must be tunable for a variety of applications.

One approach to provide power to low power, small scale computers is to use a solar cell with a thin film of Cu₂ZnSn(S,Se)₄ (CZTSSe) materials as the light absorbing layer. CZTSSe materials are abundant on earth and provide advantages of stability and low toxicity. In contrast to other materials (e.g., CdTe or GaAs) that are toxic and non-tunable, CZTSSe materials have a tunable band gap that allows the material to absorb sunlight or low room light. Although other materials (e.g., crystalline Si) are non-toxic, thicknesses of at least 180 microns must be used to achieve sufficient light absorption, which prevents the ability to use crystalline Si in small flexible solar cells.

Although CZTSSe materials offer advantages in small PV devices, there are still drawbacks to current methods used to adjust the bandgap of CZTSSe materials. For example, H₂S, which is commonly used to adjust the band gap of semiconducting light absorbing materials, such as CZTSSe materials, is highly toxic. Further, using elemental sulfur generally results in devices that are not operational, and elemental sulfur evaporation can result in uneven films that are difficult to reproduce. Sulfur generally results in defective film surfaces that prevent the fabrication of high efficiency devices, particularly when using large amounts of sulfur that are needed to appropriately tune the band gap and allow them to effectively absorb room light.

Turning now to an overview of the aspects of the invention, one or more embodiments of the invention address the above-described shortcomings of the prior art by providing methods for fabricating devices and resulting devices that optimize the combination of elements in a CZTSSe material by increasing the ratio of S to Se, which can achieve the high voltage and sufficient current necessary to power the computer. The CZTSSe materials are incorporated into solar cells that are connected in series and integrated with a battery to form a photovoltaic device that allows for band gap tuning to achieve the desired open circuit voltage.

The above-described aspects of the invention address the shortcomings of the prior art by providing methods for fabricating and resulting photovoltaic cells that have the ability to harness low light (e.g., an office light level of 500 lux in some embodiments) to power a low power autonomous computer with sufficient open circuit voltage and efficiency.

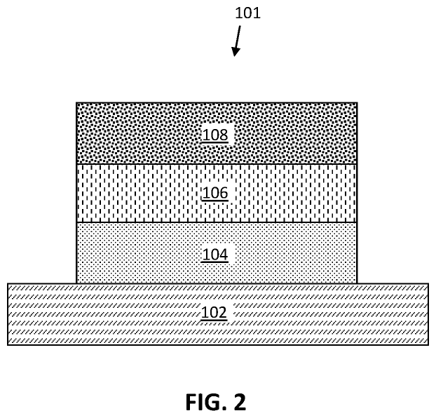

Turning now to a more detailed description of aspects of the present invention, FIG. 2 depicts a cross-sectional side view of a solar cell 101 (also referred to as a solar cell stack) according to embodiments of the invention. To fabricate the solar cell 101, a substrate 102 is initially provided. Suitable substrate 102 materials include, but are not limited to, glass, plastic, ceramic, and metal foil (e.g., aluminum, copper, etc.), or a combination thereof. The substrate 102 typically includes a conductive back contact layer, for example, molybdenum. This layer is partly transformed into a Mo(S,Se)₂ interlayer between the back contact and the absorber layer during high temperature processing as a result of its contact with the light absorbing layer 104.

A light absorbing layer 104 is formed on the substrate 102 and includes a p-type, semiconducting chalcogenide material (CZTSSe) including copper (Cu), zinc (Zn) and tin (Sn), sulfur (S), and selenium (Se). CZTSSe material is naturally p-doped due to intrinsic defects, and thus behaves as a p-type semiconductor. During operation, the light absorbing layer 104 generates a population of electrons and holes (electron hole pairs) when exposed to light.

According to an exemplary embodiment, the light absorbing layer 104 is formed using a solution-based approach. The light absorbing layer 104 components (Cu, Zn, Sn and S and Se) are dissolved in a solvent, such as hydrazine or a hydrazine-water mixture, and then deposited onto the substrate 102 using a suitable deposition process such as, but not limited to, solution coating, evaporation, electrochemical deposition, and sputtering. The individual components can be in the form of elements, salts or other compounds. In the solution process, any number of layers can be deposited to form the desired thickness. After depositing each layer, annealing is performed to intersperse and react the elements throughout the layer to increase the compositional uniformity of the film. By way of example only, annealing can be performed at a temperature of from about 100 degrees Celsius (° C.) to about 500° C., for a duration of between about 1 second to about 1 hour.

Once the light absorbing layer 104 reaches the final desired thickness, the light absorbing layer 104 on the substrate 102 is put into an enclosed environment with elemental sulfur, and a final anneal is performed as described above. The elemental sulfur can be in a solid form that is volatized during the anneal, or the elemental sulfur can be in a gaseous form. When in a solid form, the elemental sulfur can be distributed around the light absorbing layer 104 within the enclosed environment. A “hard bake” anneal is then performed at a temperature of from about 500° C. to about 700° C., e.g., from about 550° C. to about 650° C., for a duration of about 1 second to about 10 minutes. During the hard bake anneal, a portion of selenium (Se) in the CZTSSe material is replaced with sulfur (S) to increase the ratio of S to Se and provide a sulfur enriched CZTSSe material. The band gap of the CZTSSe material is altered, along with the achievable open circuit voltage, by increasing the S to Se ratio in the material. According to one or more embodiments, prior to S enrichment, the [S]/[S]+[Se] ratio is −0.1 and following S enrichment this ratio increases to ˜0.5-0.9. According to other embodiments, the concentration ratio of [S]/[S]+[Se] after enrichment is about 0.01 to 1.0.

Following the hard bake anneal, the S-enriched CZTSSe material is annealed in air at a low temperature. By way of example, the temperature is in a range of about 200° C. to about 475° C., for a duration in a range of about 1 minute to about 20 minutes. After the air anneal, the stack is allowed to cool. Annealing in air passivates crystalline grain boundaries in the films through diffusion of O₂.

Following annealing in air, the residual secondary surface secondary phases can removed. Secondary polycrystalline phase can form on the surface of the CZTSSe layer, and etching can be used to remove these secondary phases and degraded portions of the film from the surface to provide relatively pure single-phase CZTSSe, which improves solar cell effectiveness. According to an exemplary embodiment, the CZTSSe material of the light absorbing layer 104 is etched using a solution of KCN.

A buffer layer 106 is formed on the light absorbing layer 104. The buffer layer 106 is an n-type, semiconducting material including, but not limited to, zinc sulfide (ZnS), cadmium sulfide (CdS), indium sulfide (InS), oxides thereof, and/or selenides thereof. Accordingly, a p-n heterostructure is formed with the p-type light absorbing layer 104 and the n-type buffer layer 106. By way of example only, the buffer layer 106 can be formed by depositing the respective buffer layer material on the light absorbing layer 104 using vacuum evaporation, chemical bath deposition, electrochemical deposition, atomic layer deposition, successive ionic layer absorption and reaction (SILAR), chemical vapor deposition, sputtering, spin coating, doctor blading or physical vapor deposition to a thickness of from about 1 nm to about 1,000 nm. During operation, the buffer layer 106 collections electrons.

A top electrode 108 is then formed on the buffer layer 106. According to an exemplary embodiment, the top electrode 108 is formed from a transparent conductive material, such as doped zinc oxide (ZnO), indium-tin-oxide (ITO), doped tin oxide or carbon nanotubes. Finally, an array of thin metal lines that include, but are not limited to aluminum and/or nickel, are deposited to facilitate efficient collection of electrons generated from light absorption. The techniques for forming a top electrode 108 from these materials would be apparent to one of skill in the art and thus are not described further herein.

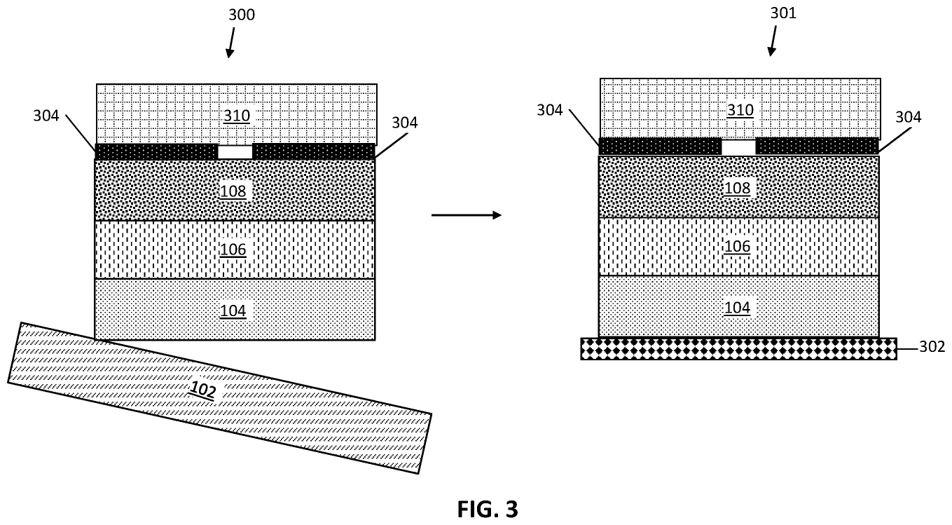

FIG. 3 depicts a method of replacing the substrate 102 of a solar cell 300 with a new back contact 302 according to embodiments of the invention by a process called “exfoliation.” Initially, a chip 310 is attached to the top electrode 108 with a layer of transparent adhesive. The chip 310 can be formed from, for example, silica or quartz, and can be fused to the top surface of the top electrode 108 with a transparent adhesive, for example a transparent epoxy. Top contacts 304 are arranged on metal lines beneath the transparent chip 310.

The substrate 102 is then removed from the solar cell 300 and replaced with a new back contact 302. By way of example, a mechanical shear impulse can be applied to the device stack 300 to remove the substrate 102 from the solar cell 300. The new back contact 302 is then deposited on the exposed surface of the light absorbing layer 104 by a low temperature process. The material of the new back contact 302 of the “exfoliated” solar cell 301 includes, but is not limited to, MoO₃ (molybdenum trioxide), platinum (Pt), molybdenum (Mo), gold (Au), or a combination thereof. According to an exemplary embodiment, the back contact 302 includes MoO₃, Au, or a combination thereof. The advantages of replacing the back contact are several-fold. MoS₂ and/or Mo(S,Se)₂ form a resistive contact that reduces the fill factor of the solar cell, thereby reducing the overall efficiency of the device. Replacing the back contact with, for example MoO₃ and Au reduces the resistance of the back contact and introduces an electric field that effectively collects holes, while also reflecting electrons and driving them to the front P-N junction of the solar cell.

FIG. 4 depicts a cross-sectional side view of solar cell 420 (light absorbing stacks) connected in series to form a photovoltaic device 400 according to embodiments of the invention. Each solar cell 420 converts harnessed light energy to current in order to charge a battery 422. Battery 422 is rechargeable and is continually recharging when the solar cell 420 is exposed to light. Each solar cell 420 includes a bottom back contact 302 (first contact), a light absorbing layer, a buffer layer, a top electrode, metal lines, and transparent chip. The back contacts 302 of each stack 420 are arranged on an insulating film 404 arranged on a battery 422. The solar cells 420 are electrically coupled (e.g., via a wiring scheme 418) to adjacent cells. A positive (+V) battery contact 408 is arranged between the battery 422 and one of the stacks 420 at a terminal end of the device 400. A negative (−V) battery contact 409 is arranged on the opposing side (second side) of the battery 422. The dividers labeled 415 are open areas between cells to insure that the individual cells are not shorted to each other. An insulator layer 412 is arranged on top. In operation, holes are collected at the bottom contacts 302, and electrons are collected at top contacts 304 arranged on the metal lines of the solar cells 420 (see also FIG. 3). Wiring 418 connects the bottom contacts 302.

The photovoltaic device 400 charges the battery 422. The battery 422, due to its chemistry, essentially supplies current at a voltage determined by the battery 422, which means that a device such as a microprocessor that is designed to run at, for example, 1.5 V will be driven by the battery 422 that drives current at 1.5 V.

Any number of solar cells 420 can be coupled to form the photovoltaic device 400. According to one or more embodiments, 9 solar cells are coupled to form the photovoltaic device 400. Yet, according to other embodiment, 1 to about 20 solar cells can be coupled to form the photovoltaic device 400.

The open circuit current achievable by the photovoltaic device 400 using the described methods is suitable for powering a low light autonomous computer (not shown), which can be coupled to the photovoltaic device 400 in any desired manner, for example, on the surface of the battery 422. According to one or more embodiments, the achievable open circuit voltage is in a range from about 1 to about 10 V. Yet according to some embodiments, the open circuit voltage is about 300 to about 1000 mV.

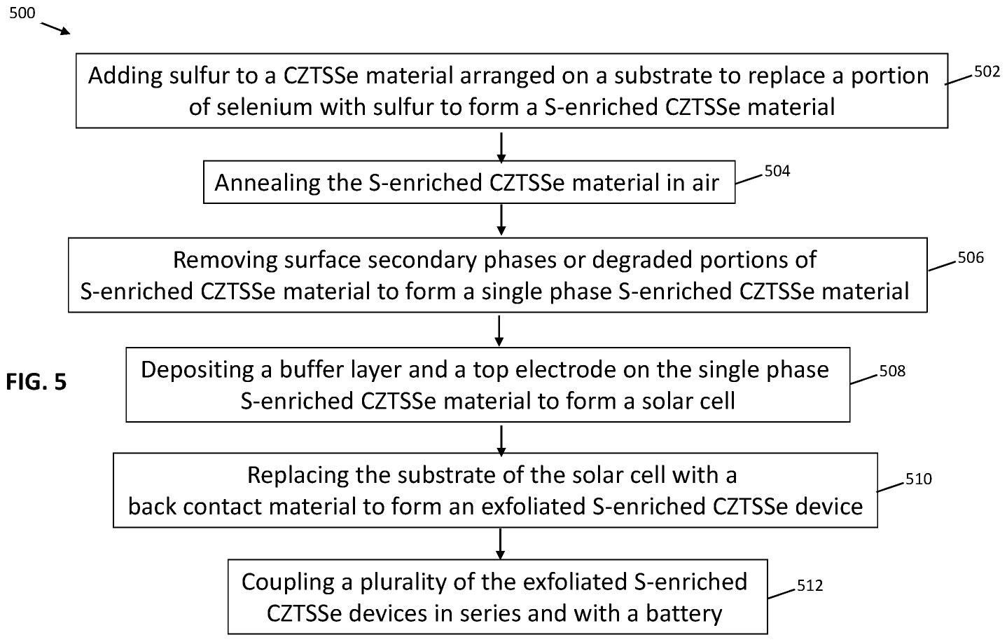

FIG. 5 depicts a flow diagram illustrating a method 500 for forming a photovoltaic device according to embodiments of the invention. Method 500 includes, as shown in box 502, adding sulfur to a CZTSSe material arranged on a substrate to replace a portion of selenium with sulfur to form a S-enriched CZTSSe material. Method 500 further includes, as shown in box 504, annealing the S-enriched CZTSSe material in air. Method 500 incudes, as shown in box 506, removing surface secondary phases or degraded portions of S-enriched CZTSSe material to form a single phase S-enriched CSTSSe material. Method 500 further includes, as shown in box 508, depositing a buffer layer and a top electrode on the single phase S-enriched CZTSSe material to form a solar cell. Method 500 includes, as shown in box 510, replacing the substrate of the solar cell with a back contact material to form an exfoliated S-enriched CSTSSe device. Method 500 further includes, as shown in box 512, coupling a plurality of the S-enriched CZSTSSe devices in series and with a battery.

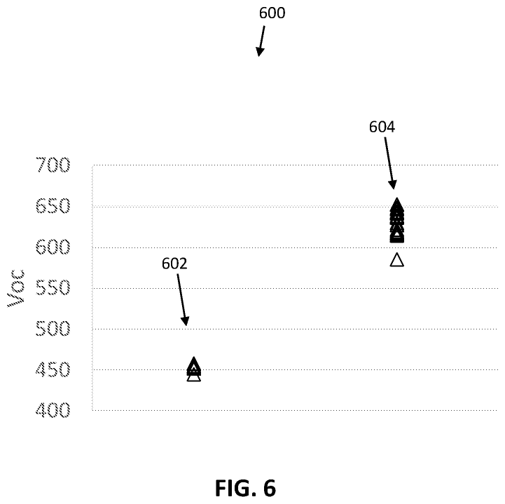

FIG. 6 depicts a graph 600 illustrating an increase in open current voltage (V_{oc}) after sulfur enrichment of a photovoltaic device according to embodiments of the invention. Compared to the V_{oc} 602 of the CZTSSe device before sulfurization, the V_{oc} 604 increased significantly. V_{oc} 602 corresponds to a PV device with a [S]/[S]+[Se]=0.1, while V_{oc} 604 corresponds to a PV device with a [S]/[S]+[Se]=0.8.

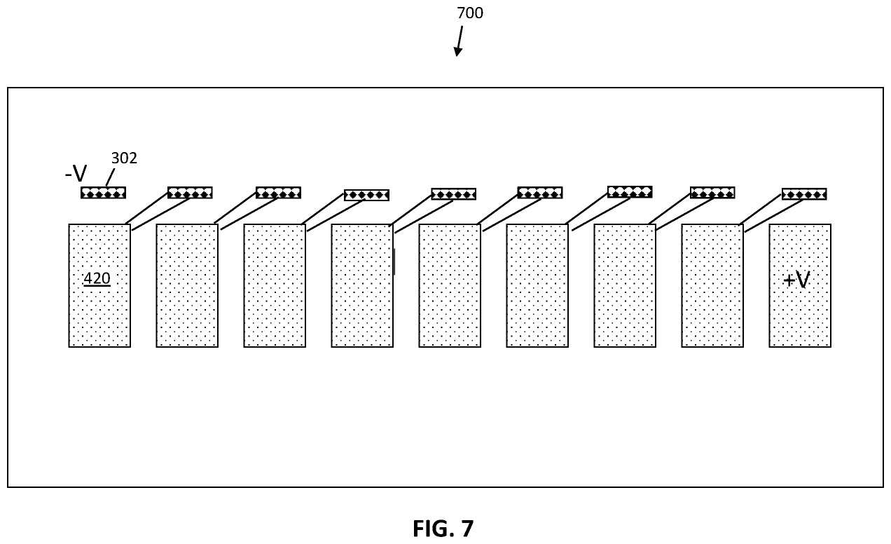

FIG. 7 depicts a diagram of a photovoltaic device 700 as viewed from the back surface according to embodiments of the invention. The solar cells 420 with back contacts 302 are connected in series.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a photovoltaic device, the method comprising:
performing fabrication operations to form the photovoltaic device, wherein the fabrication operations include:
replacing a portion of selenium with sulfur in a copper zinc tin sulfur selenium alloy (CZTSSe) material arranged on a substrate to form a sulfur enriched CZTSSe material to alter a band gap of the CZTSSe material;
removing surface secondary phases or degraded portions of the sulfur enriched CZTSSe material to form a single phase sulfur enriched CZTSSe material; and
replacing the substrate in contact with the single phase sulfur enriched CZTSSe material with a different contact material to form an exfoliated sulfur enriched CZTSSe device.

2. The method of claim 1 further comprising coupling a plurality of the exfoliated sulfur enriched CZTSSe devices in series and coupling the series with a battery to form a photovoltaic device.

3. The method of claim 1 further comprising, prior to replacing the substrate, depositing a buffer layer and a top electrode on the single phase sulfur enriched CZTSSe material.

4. The method of claim 3, wherein the buffer layer comprises an n-type material, and the top electrode comprises a transparent conductive material.

5. The method of claim 1, wherein the different contact material comprises Au and MoO₃.

6. The method of claim 1, wherein replacing a portion of selenium with sulfur comprises annealing the CZTSSe material with elemental sulfur.

7. The method of claim 1, wherein replacing the substrate comprises applying a mechanical impulse to remove the substrate and then depositing the different contact material.

8. A method of fabricating a photovoltaic device, the method comprising:
performing fabrication operations to form the photovoltaic device, wherein the fabrication operations include:
replacing a portion of selenium with sulfur in a copper zinc tin sulfur selenium alloy (CZTSSe) material arranged on a substrate to form a sulfur enriched CZTSSe material to alter a band gap of the CZTSSe material;
annealing the sulfur enriched CZTSSe material in air;
removing surface secondary phases or degraded portions of the sulfur enriched CZTSSe material to form a single phase sulfur enriched CZTSSe material; and
exposing a surface of the single phase sulfur enriched CZTSSe material in contact with the substrate and depositing a contact material on the surface to form an exfoliated sulfur enriched CZTSSe device.

9. The method of claim 8 further comprising coupling a plurality of the exfoliated sulfur enriched CZTSSe devices in series and coupling the series with a battery to form a photovoltaic device.

10. The method of claim 8 further comprising, prior exposing the surface of the single phase sulfur enriched CZTSSe material, depositing a buffer layer and a top electrode on the single phase sulfur enriched CZTSSe material.

11. The method of claim 10, wherein the buffer layer comprises an n-type material, and the top electrode comprises a transparent conductive material.

12. The method of claim 8, wherein the contact material comprises Au and MoO₃.

13. The method of claim 8, wherein replacing a portion of selenium with sulfur comprises annealing the CZTSSe material with elemental sulfur.

14. The method of claim 8, wherein replacing the substrate comprises applying a mechanical impulse to remove the substrate and then depositing the different contact material.

15. A photovoltaic device comprising:
a battery; and
a plurality of light absorbing stacks coupled to one another in series and arranged on the battery, each light absorbing stack of the plurality comprising:
a sulfur enriched copper zinc tin sulfur selenium alloy (CZTSSe) material arranged on a first contact;
a buffer layer arranged on the sulfur enriched CZTSSe material; and
a transparent electrode arranged on the buffer layer.

16. The photovoltaic device of claim 15, wherein the sulfur enriched CZTSSe material has a concentration ratio of [S]/[S]+[Se] of about 0.01 to 1.0.

17. The photovoltaic device of claim 15, wherein the first contact comprises Au, MoO₃, or a combination thereof.

18. The photovoltaic device of claim 15, wherein the sulfur enriched CZTSSe material comprises a substantially single phase material at an interface with the buffer layer.

19. The photovoltaic device of claim 15 further comprising an insulating layer arranged between the battery and the plurality of light absorbing stacks.

20. The photovoltaic device of claim 15, the open circuit voltage of the photovoltaic device is in a range from about 300 to about 1000 mV.
